(19) United States
(12) Patent Application Publication
(10) Pub. No.: US 2026/0052962 A1
(43) Pub. Date: Feb. 19, 2026

(54) CHEMICAL PASSIVATION OF MOLYBDENUM PLUG OR TRENCH'S OUTER SURFACE TO PREVENT MO NITRIDATION OR OXIDATION AND MAINTAIN LOW CONTACT RESISTANCE

(71) Applicant: Applied Materials, Inc., Santa Clara, CA (US)

(72) Inventors: Yi XU, San Jose, CA (US); Yu LEI, Belmont, CA (US); Rongjun WANG, Dublin, CA (US); Mohith VERGHESE, Phoenix, AZ (US); Bingqian LIU, Santa Clara, CA (US); Zheyuan CHEN, Santa Clara, CA (US); Jose ROMERO, Tempe, AZ (US); Xianmin TANG, San Jose, CA (US); Tza-Jing GUNG, San Jose, CA (US)

(21) Appl. No.: 19/290,667

(22) Filed: Aug. 5, 2025

Related U.S. Application Data
(60) Provisional application No. 63/683,734, filed on Aug. 16, 2024.

(51) Int. Cl. H01L 21/768; C23C 8/08; C23C 16/04; C23C 16/06; C23C 28/00; C23C 28/02; H01L 23/532

(52) U.S. Cl. CPC H01L 21/76831; C23C 8/08; C23C 16/045; C23C 16/06; C23C 28/023; C23C 28/322; C23C 28/34; H01L 21/76819; H01L 21/76879; H01L 23/5329

(57) ABSTRACT

A method includes forming a metal fill material on at least one electrical connection formed in a feature formed within a dielectric layer of a semiconductor device structure. The metal fill material partially fills the feature, the partially filled feature comprises the metal fill material and an exposed first portion of a sidewall of the feature that comprises the material of the dielectric layer, and a gap region formed between a second portion of the sidewall and a sidewall of the metal fill material, and performing a soaking process on the semiconductor device structure to form a passivation layer over a surface of the metal fill material and including a portion of the metal fill material disposed within the gap.

### CROSS-REFERENCE TO RELATED APPLICATION

This application claims benefit of U.S. Provisional Patent Application Ser. No. 63/683,734, filed Aug. 16, 2024, which is hereby incorporated by reference herein.

### BACKGROUND

### Field

Embodiments described herein generally relate to semiconductor device fabrication. More specifically, embodiments of the present disclosure relate to semiconductor devices that include low resistance contacts and methods of forming the same.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. An example of such a device includes memory (e.g., DRAM) and logic devices, including both planar and three-dimensional structures. An example of a three-dimensional structure is a fin field-effect transistor (finFET) device or a metal-oxide-semiconductor field-effect transistor (MOSFET) device.

In a traditional middle-of-the-line (MOL) interconnect formation process, a feature, such as a via or trench is fabricated in the semiconductor substrate. MOL contact allows connections between front-end-of-the-line (FEOL) semiconductor structures and back-end-of-the-line (BEOL) interconnects. Contacts with low resistance are desirable in semiconductor devices. However, when a MOL interconnect has a relatively high resistance, a poor connection is created at the MOL interconnect, which reduces the overall performance of the packaged semiconductor structures.

Conventional MOL and BEOL electrical connections, such as contacts, interconnects, and the like are formed by filling a feature such as a cavity, trench, or via with a conductive material. Then the feature is filled with a metal material to form a metal fill layer that serves as an interconnect between layers of the device. As devices reach the 1.4 nm node and beyond, molybdenum (Mo) is being used to replace tungsten (W) as the material of the metal fill layer due to its lower resistivity inside smaller features. However, after additional MOL or BEOL processing is performed after depositing Mo, process gases, such as nitrogen or ammonia (NH₃), cause nitridation and oxidation of the surfaces of the formed Mo metal fill layer and significantly increase the resistance of the formed interconnect due to presence of the nitrogen or oxygen containing layers formed of the exposed surfaces.

Therefore, there is a need in the art for a process that is used to protect the metal fill layer from oxidation and/or nitridation.

### SUMMARY

According to one or more embodiments, a method includes forming a metal fill material on at least one electrical connection formed in a feature formed within a dielectric layer of a semiconductor device structure. The metal fill material partially fills the feature, the partially filled feature comprises the metal fill material and an exposed first portion of a sidewall of the feature that comprises the material of the dielectric layer, and a gap region formed between a second portion of the sidewall and a sidewall of the metal fill material, and performing a soaking process on the semiconductor device structure to form a passivation layer over a surface of the metal fill material and including a portion of the metal fill material disposed within the gap.

According to one or more embodiments, a semiconductor device structure includes a first dielectric layer disposed over a substrate, a second dielectric layer disposed over the first dielectric layer, a feature formed through the first dielectric layer and the second dielectric layer, an electrical connection disposed within the feature, a metal fill material disposed over the electrical connection, and a passivation layer embedding the metal fill material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic top view of a multi-chamber processing system 100 according to one or more embodiments.

FIG. 2 is a flow diagram depicting a method of forming an electrical connection of a semiconductor structure, according to one or more of the embodiments described herein.

FIGS. 3A-3G illustrate views of various stages of forming an electrical connection of a semiconductor structure in accordance with one or more embodiments described herein

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Middle-of-the-line (MOL) and back-end-of-the-line (BEOL) electrical connections, such as interconnects, and the like are formed by filling a feature such as a cavity, trench, or via with a conductive material that is in contact with an underlying metal layer. To form the interconnect, the feature is filled with a metal material to form a metal fill layer. In one or more embodiments, subsequent BEOL or MOL process gases will cause oxidation and/or nitridation of the metal fill layer, increase the resistance of the formed interconnect, and therefore, reduce the performance of the electrical connection. Embodiments herein relate to passivating portions of the metal fill layer after the portion of the metal fill layer is deposited to prevent oxidation and nitridation (i.e., an increase in resistance) of the portion of the metal fill layer during subsequent processing.

### Multi-Chamber Processing System Example

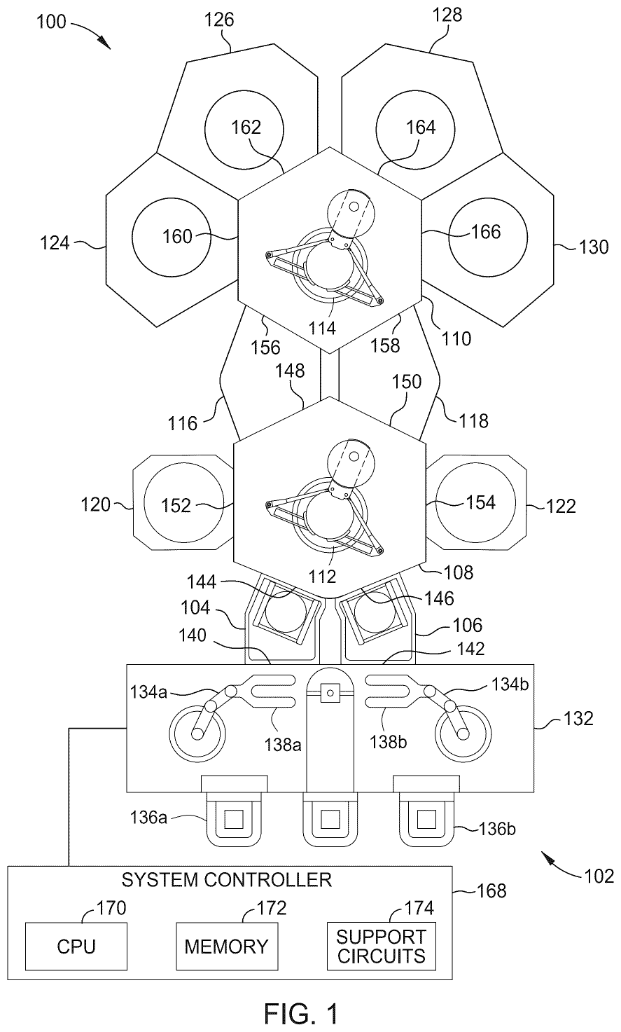

FIG. 1 illustrates a schematic top view of a multi-chamber processing system 100 according to one or more embodiments. The multi-chamber processing system 100 can be used for creating a bottom lateral recess (an etch recess) in a device substrate to anchor a metal material of an MOL or BEOL electrical connection during a chemical mechanical polishing (CMP) process. The multi-chamber processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber processing system 100 can be processed in and transferred between the various chambers without exposing the substrates to an ambient environment exterior to the multi-chamber processing system 100, for example, an atmospheric ambient environment such as may be present in a fab. The substrates can be processed in and transferred between the various chambers maintained at a low pressure, for example, less than or equal to about 300 Torr, or a vacuum environment without breaking the low pressure or vacuum environment among various processes performed on the substrates in the multi-chamber processing system 100. Accordingly, the multi-chamber processing system 100 may provide for an integrated solution for processing of substrates.

Examples of multi-chamber processing systems that may be suitably modified in accordance with the teachings provided herein include the Endura®, Producer® or Centura® integrated multi-chamber processing systems or other suitable multi-chamber processing systems commercially available from Applied Materials, Inc., located in Santa Clara, California. It is contemplated that other multi-chamber processing systems (including those from other manufacturers) may be adapted to benefit from aspects described herein.

In the illustrated example of FIG. 1, the factory interface 102 includes a docking station 132 and factory interface robots 134a-b to facilitate transfer of substrates. The docking station 132 is adapted to accept one or more front opening unified pods (FOUPs) 136a-b. In some examples, each factory interface robot 134a-b generally includes a blade 138a-b disposed on one end of the respective factory interface robot 134a-b adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, the transfer chambers 108, 110, the holding chambers 116, 118, and the processing chambers 120, 122, 124, 126, 128, 130 may be fluidly coupled to a gas and pressure control system (not specifically illustrated). The gas and pressure control system can include one or more gas pumps (for example, turbo pumps, cryo-pumps, roughing pumps) gas sources, various valves, and conduits fluidly coupled to the various chambers. In operation, the factory interface robot 134a-b transfers a substrate from the FOUP 136a-b through the port 140 or 142 to the load lock chamber 104 or 106. The gas and pressure control system then pumps down the load lock chamber 104 or 106. The gas and pressure control system further maintains the transfer chambers 108, 110 and the holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Volta™ CVD/ALD chamber, or Encore™ PVD chambers available from Applied Materials of Santa Clara, Calif.

A system controller 168 is coupled to the multi-chamber processing system 100 for controlling the multi-chamber processing system 100 or components thereof. For example, the system controller 168 may control the operation of the multi-chamber processing system 100 using a direct control of the processing chambers 104, 106, 108, 110, 116, 118, 120, 122, 124, 126, 128, 130 of the multi-chamber processing system 100 or by controlling controllers associated with the processing chambers 104, 106, 108, 110, 116, 118, 120, 122, 124, 126, 128, 130. In operation, the system controller 168 enables data collection and feedback from the respective chambers to coordinate performance of the multi-chamber processing system 100.

The system controller 168 generally includes a central processing unit (CPU) 170, memory 172, and support circuits 174. The CPU 170 may be one of any form of a general-purpose processor that can be used in an industrial setting. The memory 172, non-transitory computer-readable medium, or machine-readable storage device, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the implementations (including the methods described herein). Thus, the computer-readable storage media, when carrying computer-readable instructions that direct the functions of the methods described herein, are implementations of the present disclosure. The system controller 168 is configured to perform methods such as the method 200 stored in the memory 172.

### Processing Sequence Example

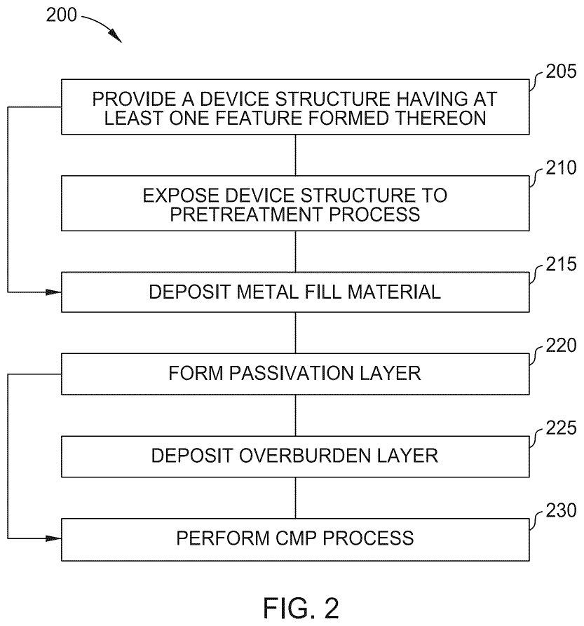

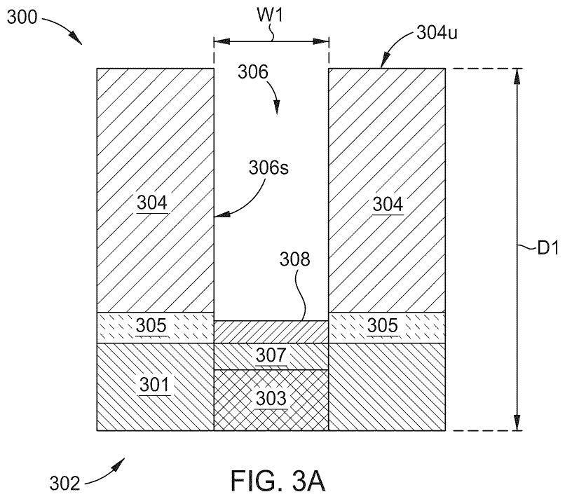

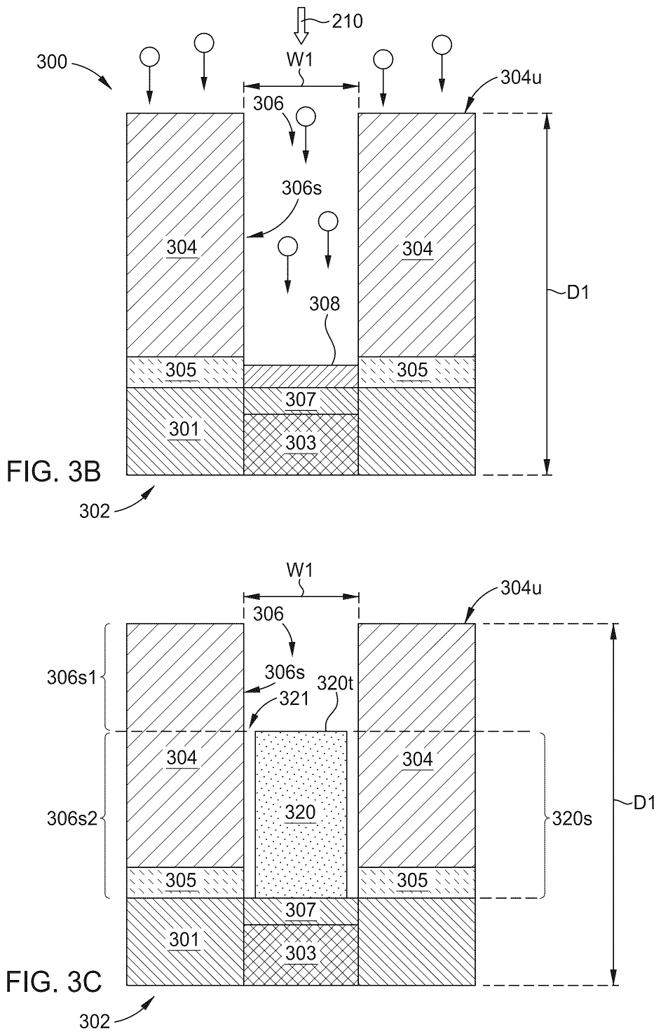

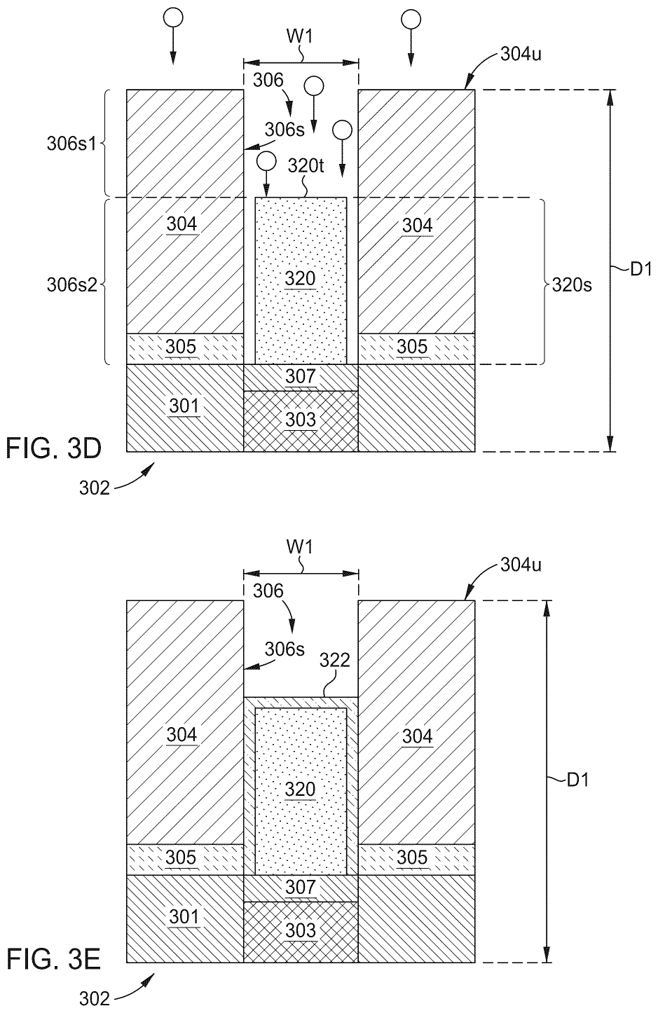

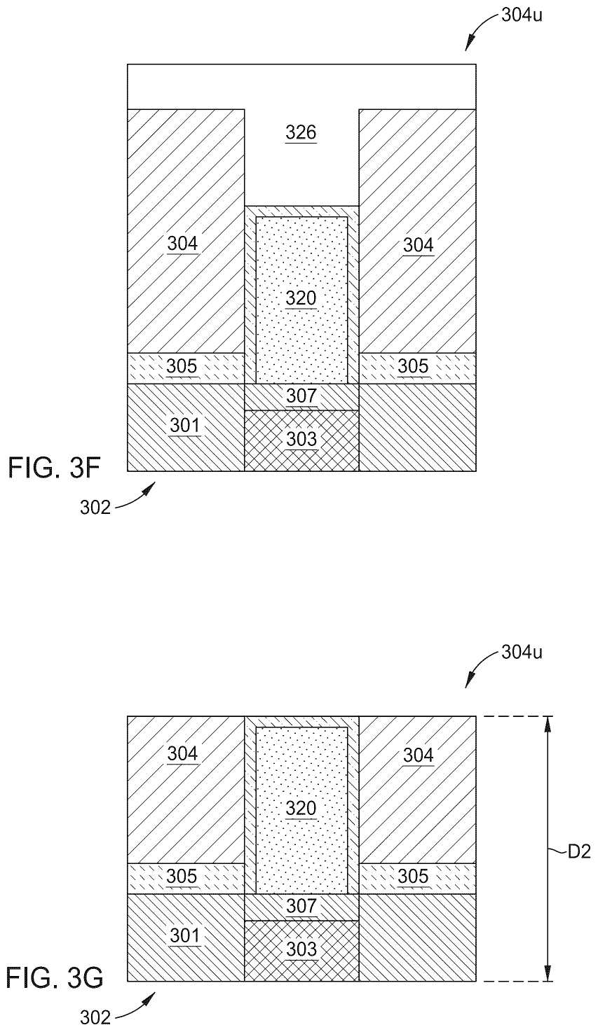

FIG. 2 is a flow diagram depicting a method 200 of forming an electrical connection of a semiconductor device structure, according to one or more of the embodiments described herein. FIGS. 3A-3G illustrate views of various stages of forming an electrical connection of a semiconductor structure in accordance with one or more embodiments described herein. Although FIGS. 3A-3G are described in relation to the method 200, the structures disclosed in FIGS. 3A-3G are not limited to the method 200, but instead may stand alone as structures that are independent of the method 200. Similarly, although the method 200 is described in relation to FIGS. 3A-3G, the method 200 is not limited to the structures disclosed in FIGS. 3A-3G but instead may stand alone independent of the structures disclosed in FIGS. 3A-3G. It should be understood that FIGS. 3A-3G illustrate only partial schematic views of a semiconductor device structure 300, and the semiconductor device structure 300 may contain any number of transistor sections and additional materials having aspects as illustrated in the Figures. It should also be noted that although the method 200 illustrated in FIG. 2 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

Referring to FIG. 2, at operation 205, a semiconductor device structure 300 having a feature formed therein is provided. FIG. 3A illustrates a cross-sectional view of the semiconductor device structure 300 during intermediate stages of manufacturing corresponding to the operation 205. The semiconductor device structure 300 includes a device substrate 302 having one or more layers formed thereon, for example, dielectric layers 301 and 304, underlying metal layer 303, and etch stop layer 305 as is shown in FIG. 3A. The device substrate 302 may be or include a bulk semiconductor substrate, a semiconductor-on-insulator (SOI) substrate, or the like, which may be doped (e.g., with a p-type dopant or an n-type dopant) or undoped. The actual base substrate on which the one or more layers, such as dielectric layers 301 and 304, underlying metal layer 303, and etch stop layer 305, are formed is not shown in FIGS. 3A-3G for simplicity of illustration and discussion. In some embodiments, the semiconductor material of the base substrate portion of the device substrate 302 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 302 may include additional materials, for example, silicide layers, metal silicide layers, metal layers, dielectric layers, etch stop layers, interlayer dielectrics, or a combination thereof.

The device substrate 302 may further include integrated circuit devices (not shown) that are formed in one or more layers below the layers shown in FIGS. 3A-3G. As one of ordinary skill in the art will recognize, a wide variety of integrated circuit devices such as transistors, diodes, capacitors, resistors, the like, or combinations thereof may be formed in and/or on the device substrate 302 to generate the structural and functional requirements of the design for the resulting semiconductor device structure 300.

The dielectric layers 301 and 304, and the etch stop layer 305 are formed over the device substrate 302. In one or more embodiments, the etch stop layer 305 is formed between dielectric layer 301 and dielectric layer 304. The dielectric layer 301 is formed over the device substrate 302 (and the additional layers formed over the device substrate 302 (if any)), the etch stop layer 305 is formed over the dielectric layer 301, and the dielectric layer 304 is formed over the etch stop layer 305. The etch stop layer 305 is sandwiched between the dielectric layers 301 and 304.

The dielectric layers 301 and 304 may include multiple layers. The dielectric layer 304 includes an upper surface 304u or field region. In some embodiments, the dielectric layers 301 and 304 include a dielectric material, such as a low k dielectric (SiCOH), silicon oxide, silicon dioxide (SiO₂), silicon nitride (Si₃N₄), silicon carbide (SiC), silicon oxynitride (SiON), aluminum oxide (Al₂O₃), aluminum nitride (AlN), a combination thereof, or multi-layers thereof. In some embodiments, the dielectric layers 301 and 304 consist essentially of silicon oxide. It is noted that the foregoing descriptors for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio. In one or more embodiments, the etch stop layer 305 includes any suitable material, including but not limited, silicon nitride, silicon carbide, metal oxide, carbon containing materials, or combinations thereof.

The semiconductor device structure 300 is patterned to form one or more feature(s) 306. The feature 306 may be a high aspect ratio (HAR) feature. In some embodiments, the feature 306 can be selected from, but not limited to, a trench, a via, a hole, a cavity, or a combination thereof. In particular embodiments, the feature 306 is a trench. In other particular embodiments, the feature 306 is a via. In some embodiments, the feature 306 extends from the upper surface 304u of the dielectric layer 304 towards the device substrate 302. The feature 306 includes sidewall surface(s) 306s that extend from the field region 304u to the device substrate 302.

In some embodiments, an electrical connection, such as electrical connection 307 is formed within the dielectric layer 301 formed at the bottom of the feature 306. The electrical connection 307 may be an interconnect, a contact structure, or the like that includes the conductive material found in the underlying metal layer 303. The electrical connection 307 is formed in a prior patterning sequence performed prior to forming the dielectric layer 304 and forming feature 306 therein. For example, as shown in FIG. 3A, the electrical connection 307 may be a contact structure that includes a conductive material. The conductive material may be formed of copper (Cu), cobalt (Co), molybdenum (Mo), tungsten (W), tantalum (Ta), titanium (Ti), or ruthenium (Ru), combinations thereof, and/or nitrides thereof. The feature 306 has a first depth “D1” from the upper surface 304u to the device substrate 302 and a width “W1” between the two sidewall surface(s) 306s. In some embodiments, the depth D1 is in a range of 2 nm to 200 nm. In some embodiments, the width W1 is in a range of 10 nm to 100 nm. In some embodiments, the feature 306 has an aspect ratio (D/W) in a range of 1 to 20.

In some embodiments, as shown in FIG. 3A, the semiconductor device structure 300 may have a native oxide layer 308 or other contaminants formed on the sidewall surface(s) 306s, the electrical connection 307, or both the sidewall surface(s) 306s and the electrical connection 307. The semiconductor device structure 300 may be exposed to atmosphere prior to or during processing, which may lead to the formation of the native oxide layer 308 on the surfaces of the feature 306 and electrical connection 307. For example, if a vacuum break occurs prior to or during the method 200, the vacuum break can lead to the formation of native oxides. In addition, other processes performed prior to or during the method 200 may lead to the formation of additional contaminants or debris on the sidewall surface(s) 306s and the electrical connection 307. In other embodiments, the native oxide layer 308 may not be present on the surfaces of the feature 306 and electrical connection 307.

Referring to FIG. 2, optionally, at operation 210, the semiconductor device structure 300 is exposed to a pretreatment process. FIG. 3B illustrates a cross-sectional view of a semiconductor device structure 300 during intermediate stages of manufacturing corresponding to the operation 210. The pretreatment process of operation 210 can include one or more native oxide or contamination removal processes for removing the contamination and/or native oxide layer 308 (if present). The pretreatment process of operation 210 can include one more clean processes. Any suitable clean process may be performed. The clean process may include a plasma etch process, such as a two-part dry chemical clean process using NF₃ and NH₃, an H₂ and O₂ plasma etch process, an H₂ plasma etch process, or a combination thereof.

In one or more embodiments, which can be combined with other embodiments, the feature 306 is exposed to a clean process and/or a degas process prior to formation of one or more conformal/non-conformal layers. For example, if the feature 306 includes silicon, the Applied Materials SICONI® clean processes may be performed for removing oxide from the surfaces of the substrate and feature. The SICONI® clean process removes native oxide through a low-temperature, two-part dry chemical clean process using NF₃ and NH₃. The clean process may be performed in a processing chamber positioned on a cluster tool, for example, the multi-chamber processing system 100 (see FIG. 1). Exemplary pre-clean chambers in which the dry clean process of operation 210 may be performed include the SICONI® clean chamber and the Preclean XT chamber available from Applied Materials, Inc., of Santa Clara, Calif.

In one or more embodiments, which can be combined with other embodiments, the substrate and the feature may be exposed to a fluorine-containing precursor and a hydrogen-containing precursor in a two-part dry chemical clean process. In one or more embodiments which can be combined with other embodiments, the fluorine-containing precursor may include nitrogen trifluoride (NF₃), hydrogen fluoride (HF), diatomic fluorine (F₂), monatomic fluorine (F), fluorine-substituted hydrocarbons, combinations thereof, or the like. In one or more embodiments, which can be combined with other embodiments, the hydrogen-containing precursors may include atomic hydrogen (H), diatomic hydrogen (H₂), ammonia (NH₃), hydrocarbons, incompletely halogen-substituted hydrocarbons, combinations thereof, or the like.

In one or more embodiments, which can be combined with other embodiments, the first part of the two-part dry clean process includes using a remote plasma source to generate an etchant species, for example, ammonium fluoride (NHF₄), from the fluorine-containing precursor, for example, nitrogen trifluoride (NF₃), and the hydrogen-containing precursor, for example, ammonia (NH₃). By using a remote plasma source, damage to the substrate may be minimized. The etchant species may then be introduced into a pre-clean chamber, for example, the processing chamber 120, 122 depicted in FIG. 1, and condensed into a solid by-product on the surface of the substrate through a reaction with the native oxides present on the surface. The second part of the two-part dry clean process may then include an in-situ anneal to decompose the by-product using convection and radiation heating. The by-product then sublimates and may be removed from the surface of the feature via a flow of gas and pumped out of the pre-clean chamber.

In one or more embodiments, which can be combined with other embodiments, the pre-treatment process is a plasma treatment process. The plasma treatment process can be an inductively coupled plasma (ICP) process or a capacitively coupled plasma (CCP) process. The plasma can be formed ex-situ in a remote plasma source (RPS). The plasma can be a direct plasma formed in-situ, for example, generated within a processing region. In one or more embodiments, which can be combined with other embodiments, the plasma treatment process includes exposing the semiconductor device structure 300 to a plasma formed from a process gas including a hydrogen-containing gas. In one or more embodiments, which can be combined with other embodiments, the plasma treatment process includes exposing the substrate to a plasma formed from a process gas including both a hydrogen-containing gas and an oxygen-containing gas. In one example, the plasma treatment process includes exposing the feature 306 to an ICP formed from a process gas including a hydrogen-containing gas and an oxygen-containing gas. The process gas may further include an inert gas, for example, argon (Ar), helium (He), krypton (Kr), or a combination thereof. In one or more embodiments, which can be combined with other embodiments, the plasma treatment process includes exposing the feature to a plasma formed form a process gas including one or more of H₂, O₂, Ar, or a combination thereof. In one or more embodiments, which can be combined with other embodiments, the plasma treatment process can include exposing the feature to a hydrogen and oxygen plasma treatment. The hydrogen and oxygen plasma treatment can include a saturation conformal treatment, which includes a longer soak time and/or high reactant treatment, to provide for good subsequent metal-fill of the feature.

In one or more embodiments, which can be combined with other embodiments, the plasma treatment process is performed at temperatures of 400 degrees Celsius or less. In one or more embodiments, which can be combined with other embodiments, the plasma treatment process includes supplying a processing gas including H₂% greater than or equal to 90% of the total flow of hydrogen and oxygen.

At operation 215 and as illustrated in FIG. 3C, the feature 306 is partially filled with a metal fill material 320 by use of selective deposition process at a first deposition rate. FIG. 3C illustrates a cross-sectional view of the semiconductor device structure 300 during intermediate stages of manufacturing corresponding to the operation 215. The metal fill material 320 can be formed by a selective bottom-up deposition process. The metal fill material 320 may be formed by any suitable deposition process such as an atomic layer deposition (ALD) process, a chemical vapor deposition (CVD) process, a hybrid ALD/CVD process, a plasma enhanced ALD (PEALD) process, a plasma enhanced CVD (PECVD) process, or the like. In some embodiments, the metal fill material 320 includes molybdenum (Mo). In other embodiments, the metal fill material 320 can be a metal selected from a group consisting of tungsten (W), cobalt (Co), copper (Cu), ruthenium (Ru), and other useful metals. In one example, precursors used during the deposition process may include molybdenum-containing precursors selected from molybdenum chlorides (e.g., MoClₓ [x=2-6]), molybdenum fluorides (MoF₆)). In some embodiments, the molybdenum chloride can be or include molybdenum (II) chloride, molybdenum (III) chloride, molybdenum (IV) chloride, molybdenum(V) chloride, molybdenum (IV) chloride, or a combination thereof. In particular embodiments, the molybdenum chloride precursor can be or include molybdenum(V) chloride that is molybdenum pentachloride (MoCl₅). Suitable examples of the metal containing precursor include Mo(NMe₂)₄, MoCl₅, MoF₆, molybdenum tetramethylheptane-3,5-dionato (Mo(thd)₃), Mo(CO)₆, and the like that are used to form a molybdenum containing layer.

In one example, the metal fill material 320 deposition process includes a CVD process that includes injecting a molybdenum containing precursor (e.g., molybdenum pentachloride (MoCl₅)), hydrogen (H₂) and a carrier gas (e.g., argon (Ar)) into a processing chamber, while maintaining the device substrate 302 disposed within the processing chamber at a temperature in a range of about 300 to 425° C. In some embodiments, an ampoule temperature of an ampoule that includes the molybdenum containing precursor, which positioned upstream of the processing chamber environment, is maintained at a lower temperature than the temperature within the processing chamber. For example, the ampoule temperature may be maintained in a range of about 60 to 90° C. In certain embodiments, a pressure within the processing chamber during the deposition process may be maintained in a range of about 5 to 50 Torr.

In one or more embodiments, as shown in FIG. 3C, the feature 306 is partially filled with the metal fill material 320, forming a partially filled feature. In some embodiments, it is desirable to only partially fill the feature 306 due to a low deposition rate commonly found when using a selective deposition process to form a conductive layer. Furthermore, due to the selectivity of the bottom-up deposition process, gaps 321 are formed between the metal fill material 320 and the sidewall surfaces 306s of the dielectric layer 304. Stated otherwise, the partially filled feature 306 includes the metal fill material 320, an exposed first portion 306s1 of a sidewall surface 306s of the feature 306 that comprises the material of the dielectric layer 304, and a gap region (i.e., gaps 321) formed between a second portion 306s2 of the sidewall surface 306s of the feature 306 and a sidewall 320s of the metal fill material. The gaps 321 are easily penetrated by ammonia (NH₃) nitrogen (N* or N₂), oxygen (O₂), water (H₂O), or any other processing gas used during subsequent BEOL and MOL processing. The penetration of the gaps 321 by processing gases causes oxidation and/or nitridation of the exposed surfaces of the metal fill material 320. For example, if the metal fill material 320 comprises Mo, after exposure to nitrogen and/or NH₃, the metal fill material 320 may be surrounded by a molybdenum nitride layer (MON). Stated otherwise, the gaps 321 may be filled and a top surface 320t of the metal fill material 320 may be covered with the MoN layer (or any other oxidation or nitridation layer). However, as noted above, the MoN layer (i.e., the oxidation/nitridation) of the metal fill material 320 increases the resistance of an interconnect formed of the metal fill material 320. Therefore, embodiments, herein relate to forming a passivation layer on the top surface 320t and within the gaps 321 to prevent oxidation and/or nitridation of the metal fill material 320.

At operation 220 a passivation layer 322 is formed over the metal fill material 320. FIGS. 3D-3E illustrate a cross-sectional view of the semiconductor device structure 300 during intermediate stages of manufacturing corresponding to the operation 220. As illustrated in FIG. 3E, in one or more examples, the passivation layer 322 is formed over the top surface 320t and within the gaps 321. In one or more embodiments, the chemistry of the passivation layer 322 is configured such that the passivation layer 322 prevents nitridation and/or oxidation of the metal fill material 320 while having no effect on the resistance and electrical operation of the semiconductor device structure 300. In one or more embodiments, the passivation layer 322 may include, but is not limited to, a silicon (Si) containing passivation layer 322, a boron (B) containing passivation layer 322, an aluminum (AI) containing passivation layer 322, a germanium (Ge) containing passivation layer 322, or the like.

As illustrated in FIG. 3D, in one or more embodiments, the passivation layer 322 is deposited using a soaking process. The soaking process may include soaking the semiconductor device structure 300 in a processing chamber at a desired temperature, pressure, and time, such as the processing chambers 126, 128, 130 (FIG. 1), using a soaking gas precursor. In one or more embodiments, the soaking gas precursor includes, but is not limited to, a Si containing soaking gas precursor, a B containing soaking gas precursor, an Al containing soaking gas precursor, or a Ge containing soaking gas precursor. Si containing soaking gas precursors include, but are not limited to, silane (SiH₄), chlorosilane (SiH₃Cl), dichlorosilane (SiH₂Cl₂), trichlorosilane (SiHCl₃), silicon tetrachloride (SiCl₄), disilane (Si₂H₆), hexachlorodisilane (Si₂Cl₆), silicon hydrochlorides (Si₂HₓCl_{y} [x=0˜6, y=0˜6], or the like. B containing soaking gas precursors include, but are not limited to, biborane (VI) (B₂H₆), boron trichloride (BCl₃), boron hydrochlorides (e.g., B₂HₓCl_{y} [x=0˜6, y=0˜6]), or the like. Al containing soaking gas precursors include, but are not limited to, Trimethylaluminium (TMA), Triethylaluminum (TEA), or the like. In other embodiments, Ge containing soaking gas precursor include, but are not limited to, germanium (IV) hydride (GeH₄).

The precursor gas permeates over the top surface 320t of the metal fill material 320 as well as penetrates the gaps 321. The precursor gas is absorbed by the outer surface of the metal fill material 320, forming the passivation layer 322. Stated otherwise, the passivation layer 322 surrounds all previously exposed surfaces of the metal fill material 320, and thus embeds the metal fill material 320 in the passivation layer 322. The chemistry of the passivation layer 322 depends on the precursor gas. Si based precursor gases form a Si containing passivation layer 322. Boron (B) based precursor gases form a boron containing passivation layer 322. Aluminum (Al) based precursor gases form an aluminum containing passivation layer 322. Germanium (Ge) based precursor gases form a germanium containing passivation layer 322. Optionally, in one or more embodiments, a preclean process may be performed prior to depositing the passivation layer 322 to improve formation of the passivation layer 322. The preclean treatment can be a plasma based or thermal based process.

In one or more examples, the soaking process may be performed at a chamber pressure of about 1 Torr to about 100 Torr. The soaking process may include flowing the precursor gas in the presence of a carrier gas, such as argon (or another noble gas), at flow rate of about 5 sccm to about 2000 sccm, for example, 500 sccm. The soaking process may be performed for a period of time of about 1 second to about 1500 seconds, such as 600 seconds. The soaking process may be performed at a process chamber temperature of about 200° C. to about 500° C., for example, 450° C.

At operation 225, an overburden layer 326 is deposited at a second deposition rate. FIG. 3F illustrates a cross-sectional view of the semiconductor device structure 300 during intermediate stages of manufacturing corresponding to the operation 225. As shown in FIG. 3F, the overburden layer 326 is deposited in the feature 306 such that it fills the remainder of the feature 306. Suitable methods for depositing the overburden layer 326 include CVD processes, ALD processes, PECVD processes, physical vapor deposition (PVD), PEALD processes, or the like. An overburden layer 326 CVD and/or PECVD deposition process may include concurrently flowing (co-flowing) a precursor gas, and a reducing agent. In at least one embodiment, co-flowing a precursor gas and a reducing agent can comprise alternating sequential repetitions of exposing the substrate to the precursor gas, and the reducing agent. The overburden layer 326 ALD and/or PEALD process may include sequential repetitions of exposing the device substrate 302 to a precursor gas, then exposing the substrate to a reducing agent. The ALD and/or PEALD may further include purging the processing volume between exposing the substrate to the precursor gas, and the reducing agent by flowing an inert gas thereinto. In one or more examples, the precursor gas includes, but is not limited to, tungsten hexafluoride (WF₆), molybdenum(V) chloride, or combinations thereof, and the reducing agent includes, but is not limited to, hydrogen (H₂). In one or more embodiments, the overburden layer 326 may be the same material or different material than the metal fill material 320. In one or more embodiments, the overburden layer 326 may include a metal, including, but not limited to, Mo, Co, Cu, W, Ta, Ti, Ru, or combinations thereof. In one or more examples, the overburden layer 326 deposition process is a conformal deposition process that fills the feature 306 (i.e., covers the passivation layer 322) and covers the field region 304u of dielectric layer 304.

In one or more embodiments, prior to depositing the overburden layer 326, a nucleation layer may be formed on the surface of the passivation layer 322. In one embodiment, the nucleation layer is formed on the metal fill material 320. In one or more examples, the nucleation layer is formed over the top surface 320t of the metal fill material 320, the passivation layer 322, the field region 304u, and the exposed sidewalls 304s of the dielectric layer 304 within the feature 306. The nucleation layer may be formed using any suitable deposition process such as ALD, CVD, PEALD, PECVD, or the like. The nucleation layer may be used to promote the initiation, growth and adhesion (i.e., promote conformal deposition) of the subsequently formed overburden layer 326 to the dielectric layer 304 and the passivation layer 322 that would not occur on the bare dielectric layer 304.

In other embodiments, a barrier layer may be deposited prior to the deposition of the overburden layer 326. In one or more examples, the barrier layer is formed over the top surface 320t of the metal fill material 320, the passivation layer 322, the field region 304u, and the exposed sidewalls 304s of the dielectric layer 304 within the feature 306. In one or more examples the barrier layer may include a metal material such as tantalum, titanium, cobalt, or the like. The barrier layer may be used to promote the initiation, growth and adhesion (i.e., conformal deposition) of the overburden layer 326 over the dielectric layer 304 and the metal fill material 320 that would not occur on the bare surface of the dielectric layer 304. The barrier layer may be formed using any suitable deposition process such as ALD, CVD, PEALD, PECVD, or the like. In one or more embodiments, the nucleation layer may be deposited over the barrier layer or the barrier layer may function as the nucleation layer.

In one or more embodiments, operation 225 is optional, and the method 200 may proceed to operation 230 after the deposition the metal fill material 320 during operation 215.

At operation 230, a chemical mechanical polishing (CMP) process is performed on the semiconductor device structure 300. FIG. 3G illustrates a cross-sectional view of the semiconductor device structure 300 during intermediate stages of manufacturing corresponding to the operation 230. In one or more embodiments, the CMP process is used for planarizing the semiconductor device structure 300. Stated otherwise, the CMP process planarizing the semiconductor device structure 300 includes removing portions of the field region 304u of the dielectric layer 304 until the passivation layer 322 and the field region are flush. Stated otherwise, the first depth D1 is reduced to a second depth D2 to the remove of portions of the field region 304u. In some embodiments, the second depth D2 formed during operation 230 is substantially equal to the height of the metal fill material 320 after performing operation 220. In one example, a thickness of the passivation layer 322 of between 1 and 50 angstroms (Å) remains over the top surface of the metal fill material 320 to assure that the surfaces of the metal fill material 320 remain encapsulated. In some embodiments, the second depth D2 formed during operation 230 is greater than the height of the metal fill material 320 after performing operation 220, such that a portion of the overburden layer 326 and the passivation layer 322 remain within the feature. In one example, a thickness of the overburden layer 326 of between 1 and 2000 angstroms (Å) remains over the top surface of the passivation layer 322 to assure that the material of the overburden layer 326, which is in good contact with the dielectric layer 304 due to the non-selective conformal deposition process used to form the overburden layer 326, prevents gases or other contaminants from entering any of the remaining open space within the gap 321 and the surfaces of the metal fill material 320 remain encapsulated. In one or more embodiments, if the overburden layer 326 is deposited (optional operation 225), the overburden layer 326 (and any other intervening layers such as the nucleation layer and/or the barrier layer) are removed by the CMP process. In other embodiments, if the overburden layer 326 is not deposited, only portions of the field region 304u are removed.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
forming a metal fill material on at least one electrical connection formed in a feature formed within a dielectric layer of a semiconductor device structure, wherein:
the metal fill material partially fills the feature,
the partially filled feature comprises the metal fill material and an exposed first portion of a sidewall of the feature that comprises the material of the dielectric layer, and
a gap region formed between a second portion of the sidewall and a sidewall of the metal fill material; and
performing a soaking process on the semiconductor device structure to form a passivation layer over a surface of the metal fill material and including a portion of the metal fill material disposed within the gap region.

2. The method of claim 1, further comprising planarizing the semiconductor device structure using a chemical mechanical polishing (CMP) process.

3. The method of claim 1, further comprising depositing an overburden layer in the feature, the overburden layer filling a remainder of the feature and covering a field region of the dielectric layer.

4. The method of claim 1, wherein the soaking process further comprises soaking the semiconductor device structure in a soaking gas precursor.

5. The method of claim 4, wherein the soaking process further comprises flowing the soaking gas precursor into a processing chamber at a flow rate of about 5 sccm to about 2000 sccm.

6. The method of claim 4, wherein the soaking gas precursor comprises a silicon (Si) containing soaking gas precursor, a boron (B) containing soaking gas precursor, an aluminum (AI) containing soaking gas precursor, or a germanium (Ge) containing soaking gas precursor.

7. The method of claim 6, wherein the Si containing soaking gas precursor comprises silane (SiH₄), chlorosilane (SiH₃Cl), dichlorosilane (SiH₂Cl₂), trichlorosilane (SiHCl₃), silicon tetrachloride (SiCl₄), disilane (Si₂H₆), or hexachlorodisilane (Si₂Cl₆).

8. The method of claim 6, wherein the B containing soaking gas precursor comprises biborane (VI) (B₂H₆) or boron trichloride (BCl₃).

9. The method of claim 6, wherein the Al containing soaking gas precursor comprises Trimethylaluminium (TMA) or Triethylaluminum (TEA).

10. The method of claim 6, wherein the Ge containing soaking gas precursor comprises germanium (IV) hydride (GeH₄).

11. The method of claim 1, wherein the passivation layer is a silicon (Si) containing passivation layer, a boron (B) containing passivation layer, an aluminum (Al) containing passivation layer, or a germanium (Ge) containing passivation layer.

12. The method of claim 1, wherein the soaking process is performed at a chamber pressure of about 1 Torr to about 100 Torr.

13. The method of claim 1, wherein the soaking process is performed at a process chamber temperature of about 200° C. to about 500° C.

14. The method of claim 1, wherein the soaking process is performed for a period of time of about 1 second to about 1500 seconds.

15. A semiconductor device structure, comprising:
a first dielectric layer disposed over a substrate;
a second dielectric layer disposed over the first dielectric layer;
a feature formed through the first dielectric layer and the second dielectric layer;
an electrical connection disposed within the feature;
a metal fill material disposed over the electrical connection; and
a passivation layer embedding the metal fill material.

16. The semiconductor device structure of claim 15, further comprising an etch stop layer disposed between the first dielectric layer and the second dielectric layer.

17. The semiconductor device structure of claim 15, wherein the passivation layer is disposed over a top surface of the metal fill material and gaps formed between sidewalls of the second dielectric layer and the metal fill material within the feature.

18. The semiconductor device structure of claim 15, wherein the metal fill material comprises at least one of: molybdenum (Mo), tungsten (W), cobalt (Co), copper (Cu), or ruthenium (Ru).

19. The semiconductor device structure of claim 15, wherein the passivation layer is a silicon (Si) containing passivation layer, a boron (B) containing passivation layer, an aluminum (Al) containing passivation layer, or a germanium (Ge) containing passivation layer.
